(19) United States
(12) Patent Application Publication
(10) Pub. No.: US 2025/0137160 A1
(43) Pub. Date: May 1, 2025

(54) ANODIZED ENCLOSURE WITH FINGERPRINT RESISTANT SEALING TECHNOLOGY

(71) Applicant: Apple Inc., Cupertino, CA (US)

(72) Inventors: Bin Ma, Suzhou (CN); Christoph Werner, Sunnyvale, CA (US); Tsung-Han Li, Hsinchu (CN); Chynna R. Lopes, Santa Cruz, CA (US); Wenyan Xue, Shanghai (CN); Ming-Hua Ding, Taoyuan City (TW); Jinwei Wang, Dongguan (CN); Bo Li, Shanghai (CN); Qikai Duan, Shanghai (CN); Judy Runge-Nussbaum, Chicago, IL (US); Masashige Tatebe, Kakogawa-shi (JP)

(21) Appl. No.: 18/900,244

(22) Filed: Sep. 27, 2024

Related U.S. Application Data
(60) Provisional application No. 63/593,955, filed on Oct. 27, 2023.
(60) Provisional application No. 63/549,988, filed on Feb. 5, 2024.

(51) Int. Cl. C25D 11/24; C25D 11/26

(52) U.S. Cl. CPC C25D 11/246; C25D 11/243; C25D 11/26

(57) ABSTRACT

An enclosure for an electronic device includes a metal substrate, a porous anodic oxide layer overlaying the metal substrate, and a hydrothermal sealant disposed on the anodic oxide layer, the hydrothermal sealant including a molten salt.

### CROSS-REFERENCE TO RELATED APPLICATIONS

This application claims the benefit of U.S. Provisional Patent Application No. 63/593,955, filed 2023 Oct. 27, entitled “ANODIZED ENCLOSURE WITH FINGERPRINT RESISTANT COATING,” and claims the benefit of U.S. Provisional Patent Application No. 63/549,988, filed 2024 Feb. 5, entitled “ANODIZED ENCLOSURE WITH FINGERPRINT RESISTANT COATING,” the disclosures of which are incorporated herein by reference in their entireties.

### FIELD

This disclosure relates generally to anodizing systems and methods. In particular, the present disclosure relates to methods and systems for providing anodic sealing technology that is hydrophobic and resistant to fingerprints.

### BACKGROUND

Sealing is an important aspect of any cosmetic anodizing process for substrates, especially aluminum alloys—the sealing can ensure the corrosion resistance of the surface and can protect the anodic oxide against uptake of dirt and loss of any incorporated coloring agents. Most sealing processes involve exposing the anodic coating to hot aqueous solutions that cause hydration of the pore structure. Although pure boiling water or steam may be used, additives can be included for improved process control and consistency, also for beneficial properties of the surface.

Screens and metal surfaces of the enclosures of cell phones, tablets, and other hand-held electronic devices are susceptible to fingerprints and smudge deposition. Such deposits can affect the aesthetic appeal of objects and decrease enjoyment of the user. When these deposits accumulate on the surfaces of electronic devices, they deteriorate display quality and can diminish one's ability to enjoyably use the device.

Currently, there are limited durable amphiphobic (oil- and water-repellent) coatings on the market for electronic devices. Aftermarket coatings are sold for hand-held electronic devices, but these coatings are of limited use because they are not wear resistant.

### SUMMARY

In at least one example of the present disclosure, an enclosure for an electronic device can include a metal substrate, a porous anodic oxide layer overlaying the metal substrate, and a hydrothermal sealant disposed on the anodic oxide layer, the hydrothermal sealant including a molten salt. In some examples, the metal substrate can include an aluminum alloy or a titanium alloy. In some examples, the molten salt can include at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, or 1-Butyl-3-methylimmidazolium hexaflurophosphate. In at least one example, the hydrothermal sealant can include a water contact angle between about 50° and about 80°. In an example, the porous anodic oxide layer further includes a dye disposed within pores, the pores including a distal portion and a proximal portion, the dye filling the pores and the sealant including a crystalline structure having a phosphate concentration gradient. In some examples, the sealant extends between about 10 nm and about 20 nm into the proximal portion of the pores. In some examples, the phosphate concentration gradient can include a high phosphate concentration at the proximal portion of the pores and a decreasing phosphate concentration towards the distal portion of the pores. In an example, the sealant can include a sealing layer on an external surface of the anodic oxide layer, the sealing layer having a thickness between about 1 nm and about 100 nm. In an example, the molten salt can include a surfactant containing phosphate.

In an example of the present disclosure, a coating for an electronic device can include an anodized oxide layer formed on a metal substrate and a hydrothermal sealant disposed in the pores of the anodized oxide layer. In some examples, the hydrothermal sealant includes an ionic molten salt. In some examples, the hydrothermal sealant can include a water contact angle between about 50° and about 80°. In some examples, the ionic sealant can include at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone, or 1-Butyl-3-methylimmidazolium hexaflurophosphate. In at least one example, the anodized oxide layer can include pores defined by openings that extend from an external surface of the anodized oxide layer and toward the metal substrate. The pores can further include a dye disposed therein. In some examples, the pores can include a distal portion and a proximal portion, the dye fills the pores, and the hydrothermal sealant includes a boehmite structure sealing the proximal portion of the pores.

In an example of the present disclosure, a method of providing a sealed anodized coating can include anodizing a substrate in an electrolyte to form an anodic oxide coating and hydrothermally sealing the anodic oxide coating with a sealant solution including an ionic liquid concentration between about 0.2 ppm and about 3.0 ppm. In some examples, the sealant solution can be between about 85° C. and about 100° C. In some examples, sealing the anodic oxide coating with a sealant solution can include dipping the anodized substrate in the sealant solution between about 20 minutes and about 90 minutes. In an example, the method can further include dyeing the anodized substrate with an organic dye prior to hydrothermally sealing the anodic oxide coating. In some examples, the ionic liquid can include at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a cross-sectional view of an enclosure for an electronic device, according to one embodiment.

FIG. 2 illustrates a magnified cross-sectional view of an enclosure with a coating including an ionic sealant disposed in pores of an anodized oxide layer, according to one embodiment.

FIG. 3 shows an IR spectroscopy measurement of the coating on an anodized aluminum substrate including a sealant having an ionic liquid, according to one embodiment.

FIG. 4 illustrates a state of a water droplet on the sealant under a static condition, showing the water contact angle, according to one embodiment.

FIG. 5 illustrates a method for providing a sealed anodized coating, according to some embodiments.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

According to some embodiments, an enclosure for a portable electronic device is described. The enclosure includes a metal substrate and an anodized layer or coating overlaying the metal substrate. The anodized layer includes pores having openings that extend from an external surface of the anodized layer and towards the metal substrate, and a sealant material that plugs the openings of the pores.

As used herein, the terms anodic film, anodized film, anodic layer, anodized layer, anodic oxide coating, anodic layer, anodic oxidized layer, metal oxide layer, oxide film, oxidized layer, and oxide layer can be used interchangeably and refer to any appropriate oxide layers. The oxide layers are formed on metal surfaces of a metal substrate. The metal substrate can include any of a number of suitable metals or metal alloys. In some embodiments, the metal substrate can include aluminum, and the aluminum is capable of forming an aluminum oxide when oxidized. In some embodiments, the metal substrate can include an aluminum alloy. In some embodiments, the metal substrate can include titanium, and the titanium is capable of forming a titanium oxide when oxidized. In some embodiments, the metal substrate can include a titanium alloy. As used herein, the terms part, layer, segment, and section can also be used interchangeably where appropriate.

The following disclosure relates to an electronic device having a coating that includes an ionic compound that increases the water contact angle of a surface of the coating, making the surface more hydrophobic without impacting the haptic properties of the material. The coating reduces the visibility of fingerprints and improves the clean-ability of the enclosure.

In a particular embodiment, the coating can include an ionic liquid. The ionic liquid can be a molten salt that includes a positively charged cation and a negatively charged anion. Typical salts, such as sodium chloride, are solid at room temperature (e.g., around 20-22° C.). However, ionic liquids can include larger compounds as substituents. In other words, ionic liquids include a comparatively large cation and a large anion. The sheer size of the substituents does not allow the ions to crystallize as a typical salt, therefore the ionic liquid remains a liquid at room temperatures.

The sealant that includes the ionic liquid can be applied to a substrate having a porous anodic oxide layer overlaying the metal substrate. The sealant can be applied as a hydrothermal sealant and as a solution that can enter the pores and seal the pores. The anodized substrate can be dipped in the solution to create a sufficient seal. After the sealing, the surface can include a water contact angle between about 50° and about 80°, which makes the surface resistant to fingerprints and smudges and makes the surface significantly more cleanable in comparison to known sealants of enclosures.

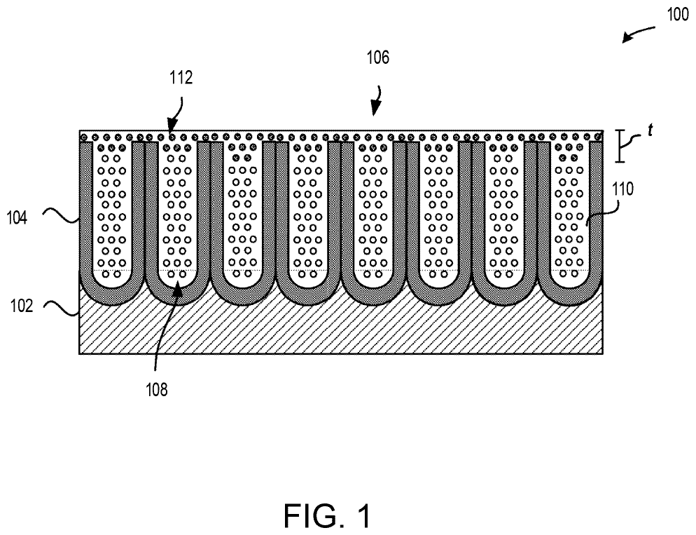

These and other embodiments are discussed below with reference to FIGS. 1-6. However, those skilled in the art will readily appreciate that the detailed description given herein with respect to these Figures is for explanatory purposes only and should not be construed as limiting. Furthermore, as used herein, a system, a method, an article, a component, a feature, or a sub-feature comprising at least one of a first option, a second option, or a third option should be understood as referring to a system, a method, an article, a component, a feature, or a sub-feature that can include one of each listed option (e.g., only one of the first option, only one of the second option, or only one of the third option), multiple of a single listed option (e.g., two or more of the first option), two options simultaneously (e.g., one of the first option and one of the second option), or combination thereof (e.g., two of the first option and one of the second option).

FIG. 1 illustrates a cross-sectional view of an enclosure 100 for an electronic device, according to one embodiment. The techniques as described herein can be used to process metallic surfaces (e.g., metal oxide layers, etc.) of enclosures of the portable and non-portable electronic devices. For example, a smartphone, a tablet computer, a smartwatch, and a portable computer can all be included as having enclosures described herein.

In some examples, the enclosure 100 can include a metal substrate 102. While the present can be applied to any substrate, they are of particular relevance to those that can be anodized. For example, the substrate 102 can include at least one of Aluminum, aluminum alloys, magnesium, titanium and/or stainless steel. However, Aluminum is common due to its high strength to weight ratio and availability. Anodized aluminum is capable of achieving many colors as dyes can be used to get the desired shade.

According to some examples, the metallic surfaces of the substrate 102 can refer to a metal oxide layer 104 that overlays a metal substrate. In some examples, the metal oxide layer 104 can be referred to as a coating or an anodic coating. In some examples, the metal oxide layer 104 is formed from the metal substrate during an anodization process. Anodizing converts a portion of the metal substrate 102 into a metal oxide, thereby creating a metal oxide layer, which is generally harder than the underlying metal substrate 102 and can act as a protective layer. The metal oxide layer 104 can function as a protective coating to protect the metal substrate 102, for example, when these portable devices are dropped, scratched, chipped, or abraded. Additionally, the metal oxide layer 104 can include pore structures that may be plugged of filled such as to external contaminants from reaching the metal substrate 102. Thus, the metal oxide layer 104 can be a porous anodic oxide layer overlaying the metal substrate 102.

In some examples, such as where the metal substrate 102 includes aluminum or an aluminum alloy, the metal oxide layer 104 can be formed over the metal substrate 102 and can include pore structures 106 (or pores) that are formed through the metal oxide layer and can extend from an external surface of the metal oxide layer and towards a barrier layer 108 that separates the metal oxide layer 104 from the underlying metal substrate 102. Additionally, according to some embodiments, each of the pore structures 106 of the metal oxide layer 104 can be capable of receiving dye particles 110 which can imbue the metal oxide layer 104 with a specific color associated with the dye particles 110. In other words, the pores can include a distal portion and a proximal portion, the dye filling the pores and the hydrothermal sealant sealing the proximal portion of the pores. In some examples, the metal oxide layer 104 can be imparted with different dye colors based on the dye particles 110 that are deposited within the pore structures 106. In some examples, the color of the metal oxide layer 104 can be characterized according to L*a*b* color-opponent dimension values. The L* color opponent dimension value is one variable in an L*a*b* color space. In general, L* corresponds to an amount of lightness. L*=0 represents the darkest black while L*=100 represents white.

According to some examples, anodized layers of enclosures may be sealed by a sealing process where pores of the anodized layers become plugged by application of a sealant 112. In some examples, the sealant can be disposed on the anodic oxide layer and seal the dye within the pores and also protect the surface of the metal oxide layer 104 from wear and potential collection of impurities.

In some examples, the sealant 112 can include an ionic liquid. The ionic liquid can be a component of the sealant. In some examples, the ionic liquid can include a molten salt. Ambient-temperature molten salts, or hydrophobic room temperature molten salts, are present in the liquid phase at standard conditions for temperature and pressure. Salts are simple, usually ionic (that is the chemical bonds are a simple ionic type) and stable compounds. In some examples, the sealant 112 can include a concentration between about 10 and about 40 ml/L ionic liquid.

In some examples, the sealant 112 can fill the pore structures 106. As such, the sealant 112 can be tightly adhered to the anodic oxide layer 104. In some examples, the dye particles 110 can be disposed within pores 106, and the dye particles and sealant 112 fill the pores. The sealant 112 can seal the pores and retain the dye particles 110 therein.

In some examples, the porous anodic oxide layer 104 can include a porosity between about 30% and about 80%. Pores are formed in the oxide layer during the anodization process, and can be spaced approximately 40-50 nanometers apart, for example. The diameter of each of the pores can range from 0.005 to about 0.05 microns, or from 0.01 to about 0.03 microns. The dimensions, however, are not intended to be limiting. In some examples, the anodic oxide 104 can include a porosity between about 30% and about 40%. In some examples, the porosity of the anodic oxide 104 can be between about 40% and about 50%, between about 50% and about 60%, between about 60% and about 70%, between about 70% and about 80% or include ranges from between about 30% and about 60% or about 40% and about 70%, as the pore sizes can vary based on the anodization process.

Sealing the surface can include sealing the pores 106 of the oxide layer 104. In some examples, the anodic oxide coating 104 can include a thickness between about 5 μm and about 20 μm. In some examples, the sealant 112 can include a thickness, designated as thickness t, between about 1 nm and about 100 nm. However, the thickness of the sealant 112 is not intended to be limiting. In some examples, the sealant 112 can be between about 5 nm and about 30 nm, between about 30 nm and about 60 nm, or between about 60 nm and about 100 nm.

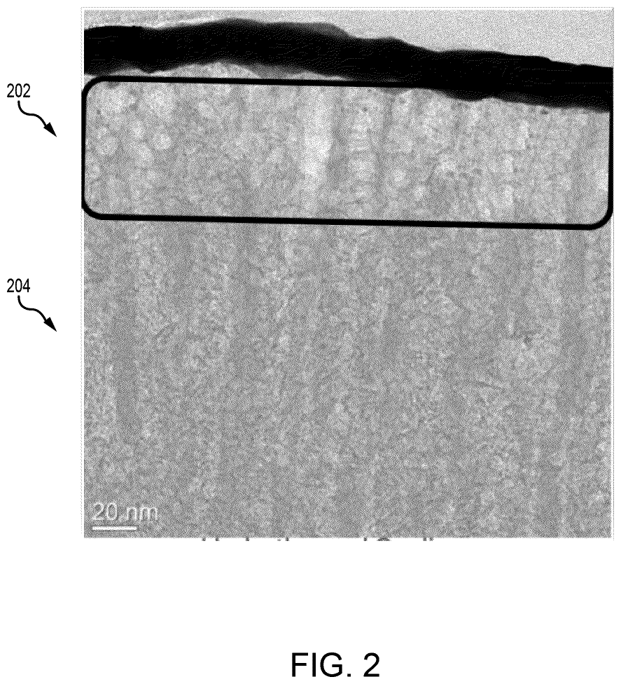

FIG. 2 illustrates a magnified cross-sectional view of a coating for an enclosure of an electronic device, with the coating including a hydrothermal sealant disposed sealing the pores of an anodized oxide layer, according to one embodiment. The anodized oxide layer is formed on a metal substrate. The hydrothermal sealant includes an ionic liquid as part of the sealant solution to be applied to the anodic oxide layer.

Region 202 illustrates a portion of the pores that includes the sealant. The sealant is shown as a lighter color of the figure and includes a clear texture change from the region 204 of the anodized oxide layer. In some examples, the hydrothermal sealant can include a boehmite structure sealing the proximal portion of the pores. Boehmite is an aluminum oxide hydroxide mineral that forms during the hydrothermal sealing process. The ionic sealant can be at least partially disposed in the pores of the anodized oxide layer. In some examples, the sealant can include a crystalline structure that includes a phosphate concentration gradient. In region 202, the sealant can include a phosphorous layer, integrated within the oxide structure. In some examples, the phosphate concentration gradient can include a high phosphate concentration at the proximal portion of the pores and the phosphate concentration decreasing towards a distal portion of the pores. In an example, the phosphorous layer can have a thickness between about 10 nm and about 20 nm. In some examples, the thickness of the phosphorous layer can be between about 10 nm and about 15 nm, between about 15 nm and about 18 nm, or between about 18 nm and about 20 nm. In some examples, the thickness of the phosphorous layer can be about 15.2 nm.

In an example, the sealant can extend between about 10 nm and about 20 nm into the proximal portion of the pores. In some examples, the sealant can cause an overfilling of the pores due to the sealing reaction described below. The presence of the ionic liquid within the sealant can be confirmed by IR spectroscopy as described in greater detail below. However, in some examples, the ionic sealant can include a molten salt. In an example, the molten salt can include a surfactant containing phosphate, which makes the sealant have an anti-smudge or anti-fingerprint effect.

Ionic liquids used in the ionic sealant can be largely made of ions. When an ionic liquid is cooled, it often forms an ionic solid-which may be either crystalline or glassy. Ionic liquids are typically colorless viscous liquids. They are often moderate to poor conductors of electricity, non-ionizing. They exhibit low vapor pressure. Many have low combustibility and are thermally stable.

In some examples, the ionic sealant can include at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate. In some examples, the acetate groups, including magnesium, sodium, calcium, and others are the major driver in establishing the sealant. In some examples, the phosphorous layer can be established as a result of the hydrophobic reaction from hydrothermally sealing the anodic oxide coating with a sealant solution.

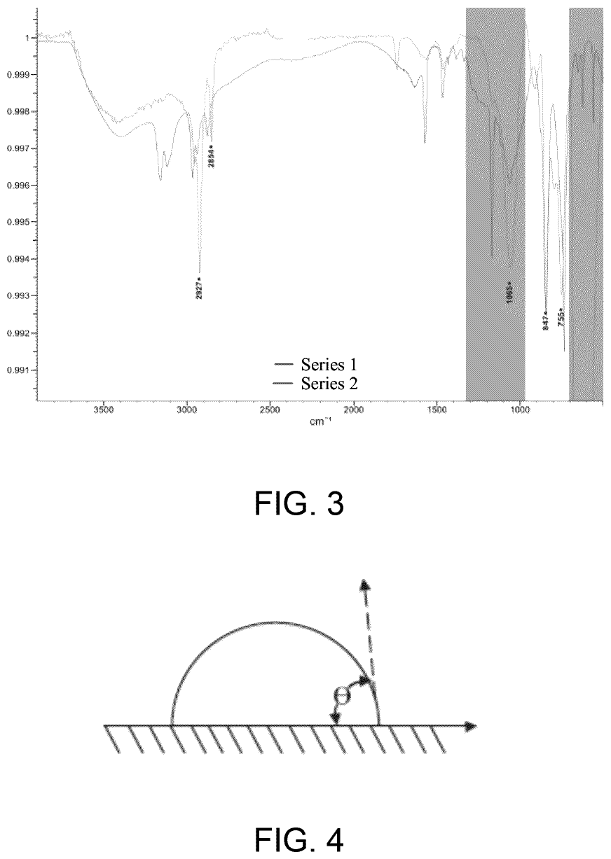

FIG. 3 shows an IR spectroscopy measurement of the coating on an anodized aluminum substrate including a sealant having an ionic liquid, according to one embodiment. Specifically, FIG. 3 is an IR spectroscopy display showing the presence of 1-Butyl-3-methylimmidazolium hexaflurophosphate (Series 2). Infrared Spectroscopy is the analysis of infrared light interacting with a molecule. This can be analyzed in three ways by measuring absorption, emission and reflection. IR Spectroscopy measures the vibrations of atoms, and based on this it is possible to determine the functional groups. IR spectroscopy is one of the most common and widely used spectroscopic techniques employed mainly by inorganic and organic chemists due to its usefulness in determining structures of compounds and identifying them. FIG. 3 is an IR measurement on the coating for an enclosure of an electronic device and the ionic sealant disposed in the pores of the anodized oxide layer. The IR measurement shows the presence of the anti-fingerprint compound within the sealant, illustrated as series 2 in the figure.

In some examples, the ionic liquid can include an ionic molten salt. FIG. 4 illustrates a state of a water droplet on the sealant under a static condition, showing the water contact angle θ, according to one embodiment. The water contact angle is the angle established between the perimeter of a liquid drop and the surface it rests on. Because contact angles depend on the interaction of the liquid with the surface, they can be used to calculate thermodynamic properties of a surface such as the surface free energy. The contact angle (also referred to as a wetting angle) is formed when a drop of liquid is placed on a material surface. The surface tension of the liquid and the attraction of the liquid to the surface causes the drop to form a dome shape. If the drop is small and the surface tension of the liquid is high, it will form a perfect hemisphere. The point where the perimeter of a liquid drop, the liquid-solid interface, and the solid all meet is called the three-phase contact point. The contact angle is defined as the angle between a tangent to the liquid surface and the solid surface at this point.

In some examples, the hydrothermal sealant can include a water contact angle between about 50° and about 80°. In some examples, the water contact angle of the hydrothermal sealant can be between about 50° and about 60°, between about 60° and about 70°, or between about 70° and about 80°. In some examples, the water contact angle can be greater than 80°.

The hydrophobicity of the sealant makes the enclosure for the electronic device anti-smudge and resistant to fingerprints. In other words, the sealant layer makes the coating and/or the enclosure fingerprint resistant and smudge resistant. While major components of a fingerprint are dead skin cells from the skin and contaminants such as dusts from an external environment, it has been known that the main cause leaving stains on the appearance of a product such as an electronic device is sebum, which is composed of lipids including triglycerides, wax monoesters, fatty acids, squalenes, cholesterols, cholesteryl esters, etc. However, another main component of the fingerprint is sweat. As such, the hydrophobicity and amphiphobic properties of the sealant combat the deposition of the fingerprint on the surface of the coating and also make the fingerprint easier to remove.

In some examples, when the fingerprint visibility of a substrate including an ionic sealant is compared with other sealants and coatings, the substrate including the ionic sealant exhibits a reduced initial visibility of a fingerprint on the enclosure surface and provides a significant clean-ability if a fingerprint is visible, relative to traditional coatings and sealing.

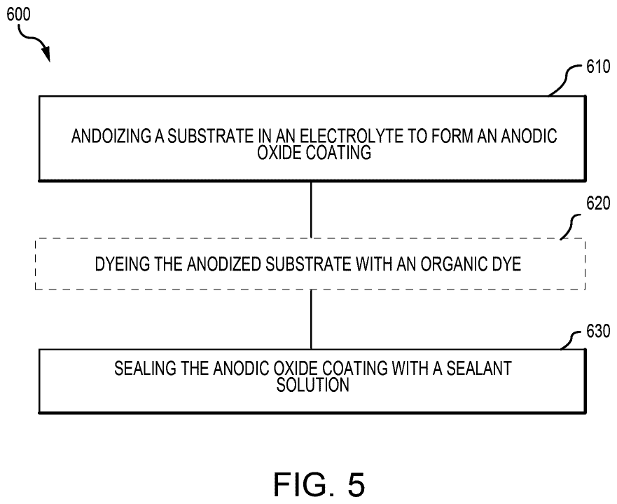

FIG. 5 illustrates a method 600 for providing a sealed anodized coating, according to some embodiments. As illustrated in FIG. 6, the method 600 can begin at step 610, where a surface of a part or an enclosure is processed. At step 610, the substrate can be anodized in an electrolyte to form an anodic oxide coating. The substrate can include aluminum or titanium. In some examples, the anodic oxide can be hydrothermally sealed and formed by using a current density between about 1.0 A/dm² and about 2.0 A/dm². Higher currents may be used if the equipment permits, and if resulting discoloration is acceptable, but defects may be observed if the coating is formed at significantly higher current densities.

The anodic oxide coating can include a thickness between about 5 μm and about 20 μm. Anodization can have a duration in a range from about 30 minutes to about 60 minutes, or from about 35 to about 55 minutes, or from about 40 to about 50 minutes, or can be about 45 minutes. The thickness of the oxide layer can be controlled in part by the duration of the anodization process. In some examples, the electrolyte can include about 5-250 g/L sulfuric acid. In one example, a concentration of about 100 g/L sulfuric acid can be used. In some examples, the electrolyte can include about 5-100 g/L of organic acid. The organic acid can include at least one of oxalic acid, glycolic acid, tartaric acid, malic acid, citric acid, or malonic acid. In some examples, the electrolyte can include a mixture of about 100 g/L sulfuric acid and about 20 g/L of an organic acid.

In some examples, the method 600 can optionally include dyeing the anodized substrate prior to hydrothermally sealing the anodic oxide coating. In some examples, the substrate can by dyed with an organic dye. The anodic pores can hold the dye that can give the substrate a desired color.

In some examples, the method 600 can further include act 630 of sealing the anodic oxide coating. In some examples, the anodic oxide coating can be sealed with a sealant that includes a concentration between about 0.2 ppm and about 0.3 ppm ionic liquid, however the concentration range is intended to be non-limiting. For example, the concentration of ionic liquid in the sealant can be between about 0.1 ppm and about 0.2 ppm, between about 0.2 ppm and about 0.3 ppm, between about 0.3 ppm and about 0.4 ppm, between about 0.4 ppm and about 0.6 ppm, or between about 0.6 ppm and about 1 ppm.

In some examples, the ionic liquid can include at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate.

In some examples, act 630 can include dipping the anodized substrate in the sealant solution between about 20 minutes and about 90 minutes, but other ranges in time can also be used. For example, the anodized substrate can be dipped in the sealant solution between about 40 minutes and about 80 minutes, between about 70 minutes and about 120 minutes, between about 90 minutes and about 150 minutes, between about 120 minutes and about 180 minutes, or between about 150 minutes and about 200 minutes. In some examples, the anodized substrate can be dipped in the sealant solution less than about 60 minutes, less than about 30 minutes, or less than about 15 minutes.

In some examples, the sealant solution can be between about 85° C. and about 100° C. when the anodized substrate is dipped in the sealant solution. However, other temperature ranges can be used. For example, the sealant solution can be between about 20° C. and about 50° C., between about 50° C. and about 70° C. between about 70° C. and about 85° C., between about 80° C. and about 90° C., or between about 90° C. and about 100° C.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

To the extent applicable to the present technology, gathering and use of data available from various sources can be used to improve the delivery to users of invitational content or any other content that may be of interest to them. The present disclosure contemplates that in some instances, this gathered data may include personal information data that uniquely identifies or can be used to contact or locate a specific person. Such personal information data can include demographic data, location-based data, telephone numbers, email addresses, TWITTER® ID's, home addresses, data or records relating to a user's health or level of fitness (e.g., vital signs measurements, medication information, exercise information), date of birth, or any other identifying or personal information.

The present disclosure recognizes that the use of such personal information data, in the present technology, can be used to the benefit of users. For example, the personal information data can be used to deliver targeted content that is of greater interest to the user. Accordingly, use of such personal information data enables users to calculated control of the delivered content. Further, other uses for personal information data that benefit the user are also contemplated by the present disclosure. For instance, health and fitness data may be used to provide insights into a user's general wellness, or may be used as positive feedback to individuals using technology to pursue wellness goals.

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (HIPAA); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of advertisement delivery services, the present technology can be configured to allow users to select to “opt in” or “opt out” of participation in the collection of personal information data during registration for services or anytime thereafter. In another example, users can select not to provide mood-associated data for targeted content delivery services. In yet another example, users can select to limit the length of time mood-associated data is maintained or entirely prohibit the development of a baseline mood profile. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, content can be selected and delivered to users by inferring preferences based on non-personal information data or a bare minimum amount of personal information, such as the content being requested by the device associated with a user, other non-personal information available to the content delivery services, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An enclosure for an electronic device, the enclosure comprising:
a metal substrate;
a porous anodic oxide layer overlaying the metal substrate; and
a hydrothermal sealant disposed on the anodic oxide layer, the hydrothermal sealant comprising a molten salt.

2. The enclosure for an electronic device of claim 1, wherein the metal substrate comprises an aluminum alloy or a titanium alloy.

3. The enclosure for an electronic device of claim 1, wherein the molten salt comprises at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate

4. The enclosure for an electronic device of claim 1, wherein the hydrothermal sealant comprises a water contact angle between about 50° and about 80°.

5. The enclosure for an electronic device of claim 1, wherein the porous anodic oxide layer further comprises a dye disposed within pores, the pores comprising a distal portion and a proximal portion, the dye filling the pores and the sealant comprising a crystalline structure including a phosphate concentration gradient.

6. The enclosure for an electronic device of claim 5, wherein the sealant extends between about 10 nm and about 20 nm into the proximal portion of the pores.

7. The enclosure for an electronic device of claim 5, wherein the phosphate concentration gradient comprises a high phosphate concentration at the proximal portion of the pores and a decreasing phosphate concentration towards the distal portion of the pores.

8. The enclosure for an electronic device of claim 1, wherein the sealant comprises a sealing layer on an external surface of the anodic oxide layer, the sealing layer comprising a thickness between about 1 nm and about 100 nm.

9. The enclosure for an electronic device of claim 1, wherein the molten salt comprises a surfactant containing phosphate.

10. A coating for an enclosure of an electronic device, comprising:
an anodized oxide layer formed on a metal substrate; and
a hydrothermal sealant disposed in the pores of the anodized oxide layer.

11. The coating of claim 10, wherein the hydrothermal sealant comprises an ionic molten salt.

12. The coating of claim 10, wherein the hydrothermal sealant comprises a water contact angle between about 50° and about 80°.

13. The coating of claim 10, wherein the hydrothermal sealant comprises at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate.

14. The coating of claim 10, wherein the anodized oxide layer comprises pores defined by openings that extend from an external surface of the anodized oxide layer and toward the metal substrate, wherein the pores further comprise a dye disposed therein.

15. The coating of claim 14, wherein the pores comprise a distal portion and a proximal portion, the dye fills the pores, and the hydrothermal sealant comprises a boehmite structure sealing the proximal portion of the pores.

16. A method of providing a sealed anodized coating, the method comprising:
anodizing a substrate in an electrolyte to form an anodic oxide coating; and
hydrothermally sealing the anodic oxide coating with a sealant solution comprising an ionic liquid concentration between about 0.2 ppm and about 3.0 ppm.

17. The method of claim 16, wherein the sealant solution is between about 85° C. and about 100° C.

18. The method of claim 16, wherein sealing the anodic oxide coating with a sealant solution comprises dipping the anodized substrate in the sealant solution between about 20 minutes and about 90 minutes.

19. The method of claim 16, further comprising dyeing the anodized substrate with an organic dye prior to hydrothermally sealing the anodic oxide coating.

20. The method of claim 16, wherein the ionic liquid comprises at least one of 1-Ethyl-3-methylimmidazolium trifluromethansulfonate, 1-Ethyl-3-methylimmidazolium hexaflurophosphate, 1-Ethyl-3-methylimmidazolium saccharinate, 1-Butyl-3-methylimmidazolium trifluromethansulfonate, 1-Butyl-3-methylimmidazolium hexaflurophosphate, 2-(Phosphonomethyl)-pentandioic acid (i.e., 2-PMPA), 2 Carboxymethyl phosphonate, nitrogen containing aromatics, benzothiazolone or 1-Butyl-3-methylimmidazolium hexaflurophosphate.
